(19) United States
(12) Patent Application Publication
(10) Pub. No.: US 2016/0118309 A1
(43) Pub. Date: Apr. 28, 2016

(54) Minimal Contact Wet Processing Systems and Methods

(71) Applicant: Intermolecular, Inc., San Jose, CA (US)

(72) Inventors: Rajesh Kelekar, Los Altos, CA (US); Satbir Kahlon, Livermore, CA (US); Robert Sculac, Lake Oswego, OR (US)

(21) Appl. No.: 14/525,944

(22) Filed: Oct. 28, 2014

(51) Int. Cl. H01L 21/66; H01L 21/288; H01L 21/67; H01L 21/311; H01L 21/3213; H01L 21/02; H01L 21/306

(52) U.S. Cl. CPC H01L 22/26; H01L 21/02057; H01L 21/02282; H01L 21/02623; H01L 21/288; H01L 21/30604; H01L 21/31111; H01L 21/31133; H01L 21/32134; H01L 21/6704; H01L 21/67075; H01L 21/67023

(57) ABSTRACT

Embodiments provided herein describe systems and methods for processing substrates. A substrate having a first region and a second region is provided. A container is positioned proximate to the first region of the substrate. The container has an opening on an end thereof adjacent to the substrate. A processing liquid is dispensed into the container such that the processing liquid contacts the first region of the substrate through the opening. The gaseous pressure in a portion of the container devoid of the processing liquid is reduced. The reduction of the gaseous pressure prevents the processing liquid from flowing from the first region of the substrate to the second region of the substrate.

### TECHNICAL FIELD

The present invention relates to systems and method for processing substrates. More particularly, this invention relates to wet processing systems and methods for semiconductor devices in a manner such that contact with the substrates is minimized.

### BACKGROUND

Combinatorial processing enables rapid evaluation of semiconductor, solar, or energy processing operations. The systems supporting the combinatorial processing are flexible and accommodate the demands for running the different processes either in parallel, serial or some combination of the two.

Some exemplary processing operations include operations for adding (depositions) and removing layers (etch), defining features, preparing layers (e.g., cleans), doping, etc. Similar processing techniques apply to the manufacture of integrated circuit (IC) semiconductor devices, thin-film photovoltaic (TFPV) devices, flat panel displays, optoelectronics devices, data storage devices, magneto electronic devices, magneto optic devices, packaged devices, and the like. As feature sizes continue to shrink, improvements, whether in materials, unit processes, or process sequences, are continually being sought for the deposition processes. However, semiconductor and solar companies conduct research and development (R&D) on full wafer processing through the use of split lots, as the conventional deposition systems are designed to support this processing scheme. This approach has resulted in ever escalating R&D costs and the inability to conduct extensive experimentation in a timely and cost effective manner. Combinatorial processing as applied to semiconductor, solar, or energy manufacturing operations enables multiple experiments to be performed at one time in a high throughput manner. Equipment for performing the combinatorial processing and characterization must support the efficiency offered through the combinatorial processing operations.

One issue sometimes associated with current combinatorial wet processing systems is that of contamination. For example, current systems may utilize an o-ring or tapered edge to contact the substrate and form a seal to keep the processing liquids on the desired portions of the substrate. This may result in unwanted particles (e.g., from the o-ring) from being left on the substrate.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a simplified schematic diagram illustrating a general methodology for combinatorial process sequence integration.

FIG. 3 is a simplified cross-sectional schematic view of a wet processing system according to some embodiments.

FIGS. 4 and 5 are isometric views of an interior of a processing chamber of the system of FIG. 3.

FIG. 6 is an isometric view of a row of wet processing units within the system of FIG. 3.

FIG. 7 is a plan view of the substrate indicating regions on the substrate corresponding to the wet processing units of the system of FIGS. 3 and 6.

FIG. 8 is a simplified cross-sectional schematic of a portion of one of the wet processing units of FIG. 6 positioned proximate to a substrate according to some embodiments.

FIG. 9 is a view of the portion of the wet processing unit of FIG. 8 taken along line 9-9;

FIG. 10 is a side view of the portion of the wet processing unit of FIG. 9 taken along line 10-10;

FIG. 11 is a simplified cross-sectional schematic of a portion of one of the wet processing units of FIG. 6 positioned proximate to a substrate according to some embodiments.

FIG. 12 is a flow chart of a method for processing a substrate according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide systems and methods for performing wet processing techniques on substrates, particularly those utilizing combinatorial techniques in which it is desirable to hold the processing liquid(s) on particular regions on the substrate.

In some embodiments, the issue of contamination caused by contact with the substrate during wet processing is addressed by utilizing reactors/containers that have minimal contact the substrate, or perhaps do not contact the substrate at all. The processing liquid is held within a container and/or on the desired portion of the substrate by applying a suction force to (i.e., by reducing the gaseous pressure of) the portion of the container above the processing liquid.

In some embodiments, the suction force allows the container to be positioned slightly above the surface of the substrate (i.e., such that a gap remains between at least a portion of the container and the substrate) to reduce the likelihood of any contaminants being left behind. However, in some embodiments, one or more protrusions are formed on the bottom edge of the container, which contact the substrate. These protrusions may facilitate consistent spacing/size of the gap between the container and the substrate, while minimizing contact between the two. In some embodiments, multiple containers are utilized and combinatorial processing techniques are used on a single substrate.

The manufacture of various devices, such as, thin-film photovoltaic (TFPV) modules, semiconductor devices, thermochromic devices, optoelectronic devices, etc., entails the integration and sequencing of many unit processing steps. For example, device manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single monolithic substrate (e.g., an integrated or short-looped wafer) without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574, filed on Feb. 10, 2006, U.S. Pat. No. 7,824,935, filed on Jul. 2, 2008, U.S. Pat. No. 7,871,928, filed on May 4, 2009, U.S. Pat. No. 7,902,063, filed on Feb. 10, 2006, and U.S. Pat. No. 7,947,531, filed on Aug. 28, 2009, which are all herein incorporated by reference. Systems and methods for HPC processing are further described in U.S. patent application Ser. No. 11/352,077, filed on Feb. 10, 2006, claiming priority from Oct. 15, 2005, U.S. patent application Ser. No. 11/419,174, filed on May 18, 2006, claiming priority from Oct. 15, 2005, U.S. patent application Ser. No. 11/674,132, filed on Feb. 12, 2007, claiming priority from Oct. 15, 2005, and U.S. patent application Ser. No. 11/674,137, filed on Feb. 12, 2007, claiming priority from Oct. 15, 2005, which are all herein incorporated by reference.

HPC processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

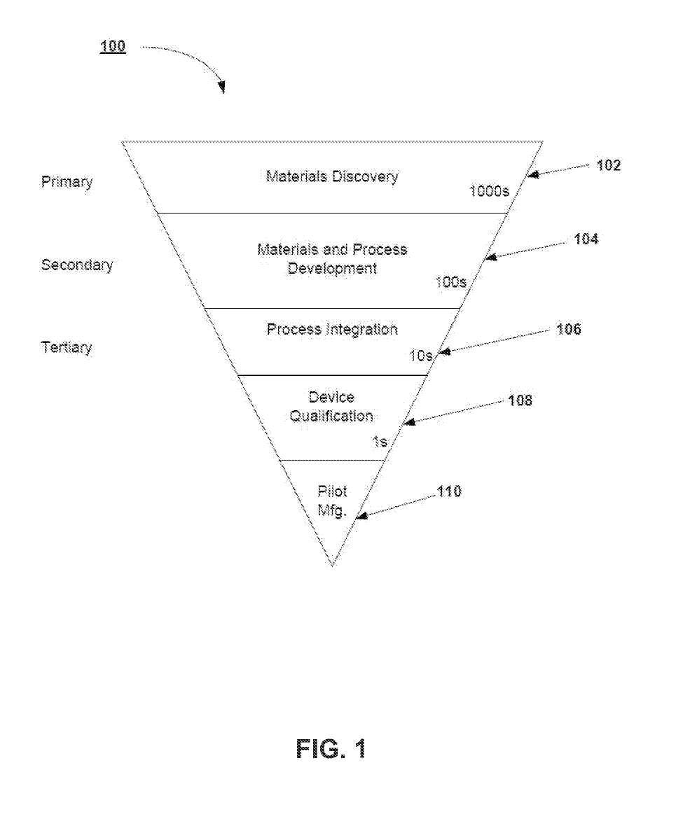

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137, filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of, for example, device manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the device. For example, such structures may include, but would not be limited to, contact layers, buffer layers, absorber layers, or any other series of layers or unit processes that create an intermediate structure found on devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

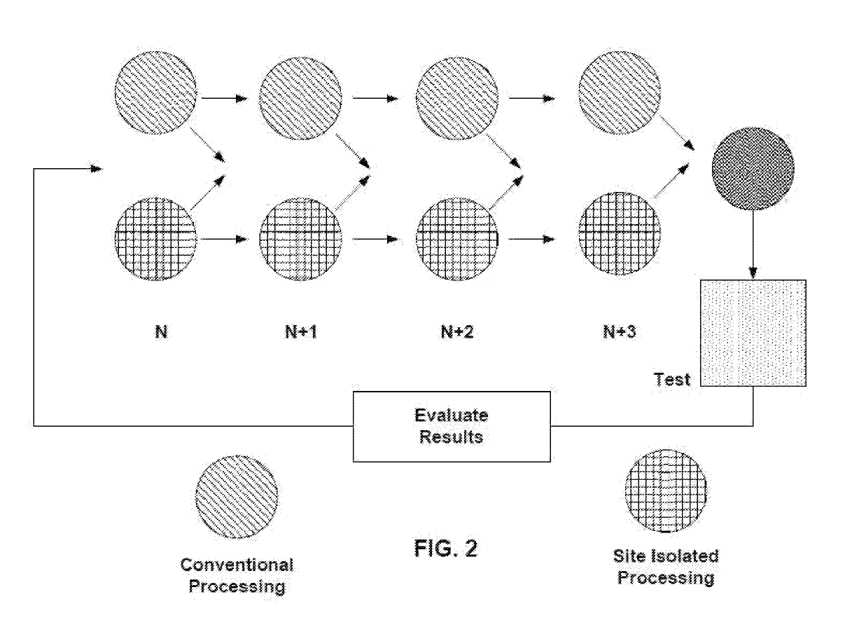

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077, filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first region and a second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in device manufacturing may be varied.

Some embodiments described herein provide systems and methods for performing wet processing on substrates, such as semiconductor substrates, in a combinatorial manner. That is, the systems and methods allow for varying processing conditions across multiple site-isolated regions on the substrate(s).

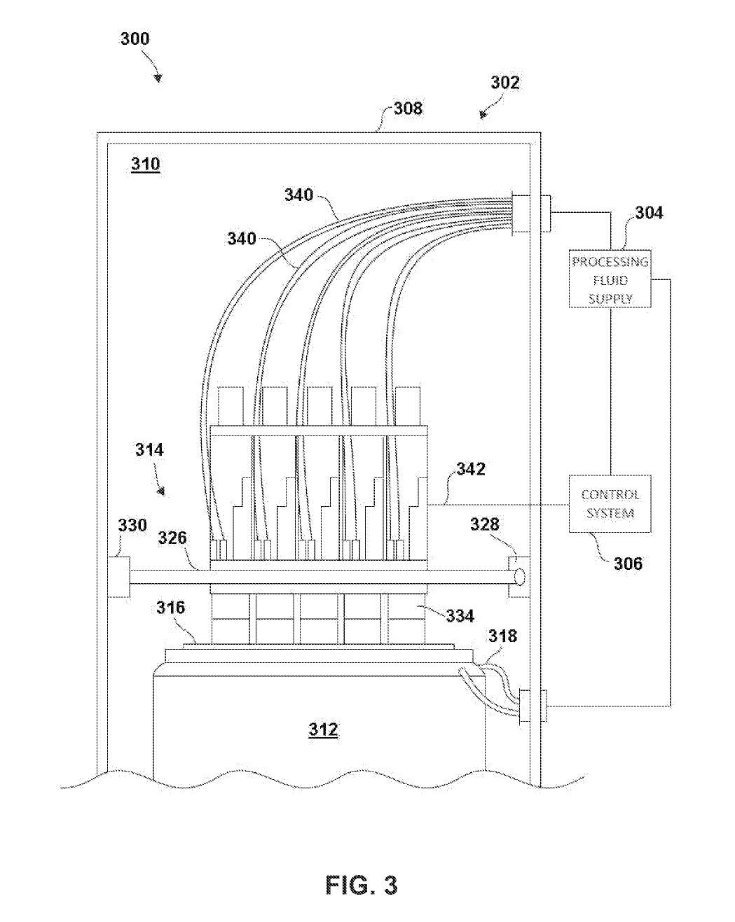

FIG. 3 illustrates a wet processing system 300 according to some embodiments. The wet processing system 300 includes a wet processing tool (and/or apparatus) 302, a processing fluid supply system 304, and a control system 306.

The wet processing tool 302 includes a housing 308 enclosing a processing chamber 310, a substrate support 312, and a wet processing assembly 314. Referring now to FIGS. 3, 4, and 5, the substrate support 312 is positioned within the processing chamber 310 and is configured to hold a substrate 316. Although not shown in detail, the substrate support 312 may be configured to secure the substrate using, for example, a vacuum chuck, electrostatic chuck, or other known mechanism. Additionally, the substrate support 312 may have a series of fluid passageways extending therethrough which are in fluid communication with the processing fluid supply system 304 via support fluid lines 318.

The substrate 316 may be a conventional, round substrate (or wafer) having a diameter of, for example, 200 millimeter (mm), 300 mm, or 450 mm. In some embodiments, the substrate 316 is a semiconductor substrate or a transparent substrate, such as glass. In other embodiments, the substrate 316 may have other shapes, such as a square or rectangular. It should be understood that the substrate 316 may be a blanket substrate (i.e., having a substantial uniform surface), a coupon (e.g., partial wafer), or even a patterned substrate having site-isolated regions (or locations) 320. The term region is used herein to refer to a localized area on a substrate which is, was, or is intended to be used for processing or formation of a selected material. The region may include one region and/or a series of regular or periodic regions pre-formed on the substrate. The region may have any convenient shape, e.g., circular, rectangular, elliptical, wedge-shaped, etc. In the semiconductor field a region may be, for example, a test structure, single die, multiple die, portion of a die, other defined portion of substrate, or a undefined area of a, e.g., blanket substrate which is defined through the processing.

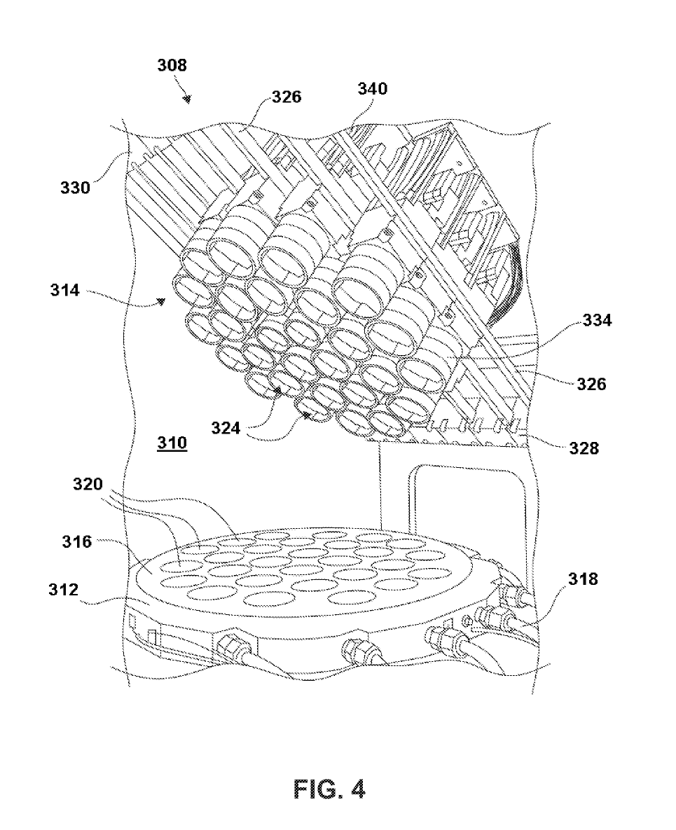

Still referring to FIGS. 3, 4, and 5, the wet processing assembly 314 includes a scaffolding 322 and an array of wet processing units 324 attached to the scaffolding 322. The scaffolding 322 includes a plurality of scaffolding bars 326 extending between end pieces 328 and 330. As shown in FIG. 4, end piece 328 is pivotably (or rotatably) coupled to the housing 308.

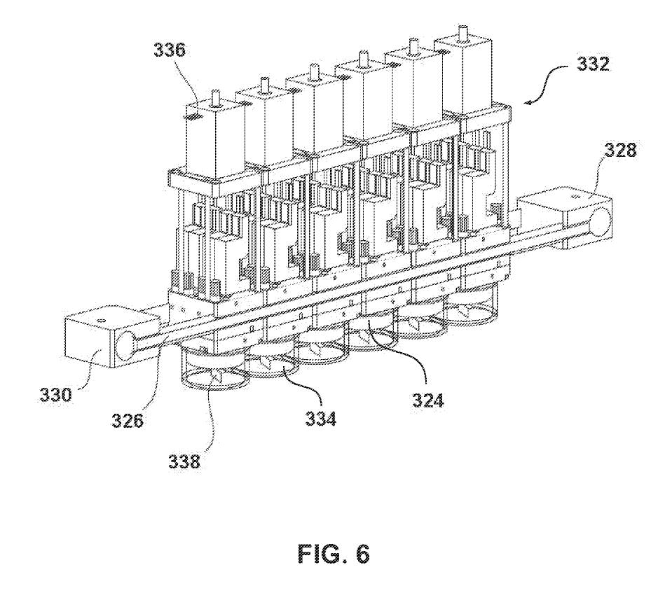

The wet processing units 324 are arranged in a series of rows (or sticks) 332, with each of the rows 332 being positioned between adjacent scaffolding bars 326. FIG. 6 illustrates one of the rows 332 of wet processing units 324. The row 332 shown in FIG. 4 includes six of the wet processing units 324. However, as shown in FIGS. 3, 4, and 5, the number of wet processing units 324 in each row 332 may differ, as is appropriate given the size and shape of the substrate 316. As shown in FIGS. 3 and 6, each of the wet processing units 324 includes, amongst other components, a liquid container (or reactor) 334, a transducer actuator 336 housed above the liquid container 334, and a transducer (i.e., megasonic transducer) 338 positioned within the liquid container 334 and coupled to the transducer actuator 336. However, in some embodiments, the wet processing units 324 do not include the transducer actuators 336 or the transducers 338.

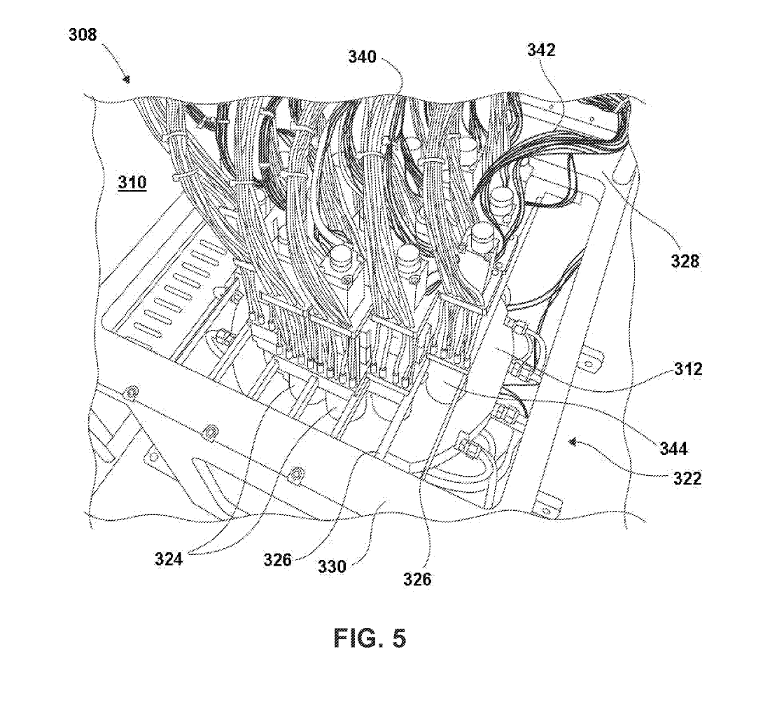

Referring again to FIGS. 3, 4, and 5, each of the liquid containers 334 is in fluid communication with the processing fluid supply system 304 via a series of fluid lines 340. Further, each of the wet processing units 324 (and/or the transducer actuators 336) is in operable communication with the control system 306 via wiring 342 (FIGS. 3 and 5).

The processing fluid supply system 304 includes one or more supplies of various processing fluids, as well as temperature control units to regulate the temperatures of the various fluids. In some embodiments, the processing fluid supply system 304 also includes one or more vacuum lines (e.g., connected to a house vacuum), at least some of which may be equipped with a liquid trap, as described below.

The control system (or controller) 306 includes, for example, a processor and memory (i.e., a computing system) in operable communication with the processing fluid supply system 304 and the wet processing units 324 and is configured to control the operation thereof as described below.

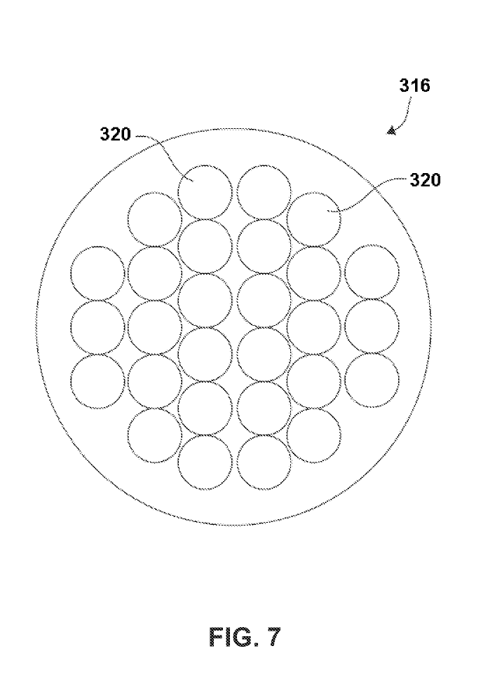

Referring again to FIGS. 3 and 4, as well as FIG. 7, after the substrate 316 is positioned on the substrate support 312 (i.e., by a robot which is not shown), the wet processing assembly 314 is lowered (or pivoted downwards) such that the liquid containers 334 of the wet processing units 324 are positioned proximate to (e.g., in contact with) the substrate 316, or a surface thereof. In some embodiments, each of the liquid containers 334 corresponds to (and/or defines) one of the site-isolated regions 320 on the substrate 316. That is, each of the liquid containers 334 may be used to perform a wet process on a respective one of the site-isolated regions as described in greater detail below.

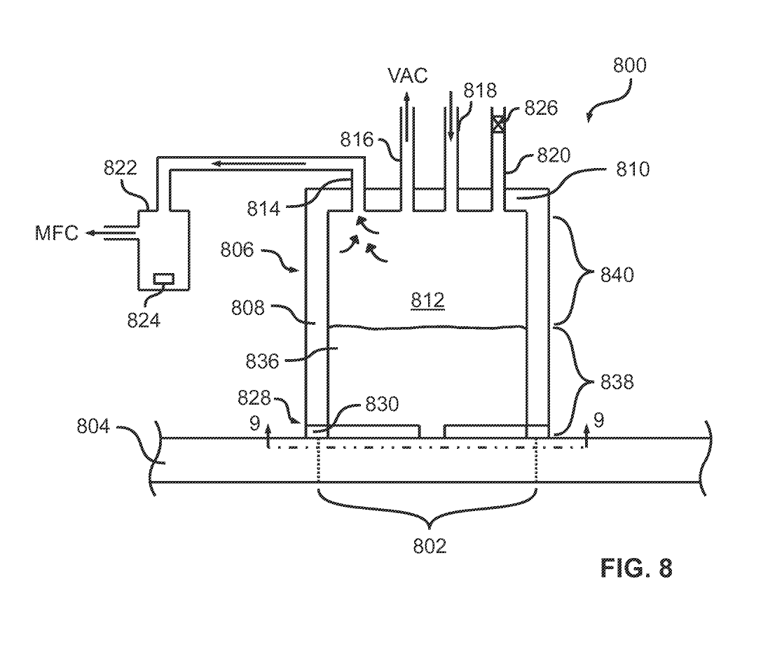

FIG. 8 schematically illustrates a wet processing unit 800, according to some embodiments, positioned above a site-isolated region 802 on a substrate 804. The wet processing unit 800 may be one of the wet processing units 324 described above, and likewise include (or substantially be formed by) a liquid container (or reactor) 806. The liquid container 806 includes a side wall 808 and a top portion (or lid) 810, which along with the substrate 804, jointly enclose (or substantially enclose) an interior 812 of the liquid container 806.

In some embodiments, a series of fluid lines 814-820 are inserted through openings (or manifolds) in the top portion 810 of the liquid container 806 and may be in fluid communication with various portions of the processing fluid supply system 304 (FIG. 3). For example, in the depicted embodiment, fluid line 814 is in fluid communication with a liquid trap 822 which includes a liquid/leak sensor 824 and is in turn in fluid communication with a mass flow controller (MFC). Although not specifically shown, it should be understood that the MFC may be coupled to a vacuum, as is the case with fluid line 816. Fluid line 818 may be in fluid communication with one or more of the processing fluid supplies within the processing fluid supply system 304. In some embodiments, fluid line 820 is in fluid communication with the atmosphere (i.e., a vent manifold or line). However, as shown, fluid line 820 may be blocked by a plug 826. Although not shown, it should be understood that in some embodiments at least some of the fluid lines 814-820 extend into the interior 812 of the liquid container 806.

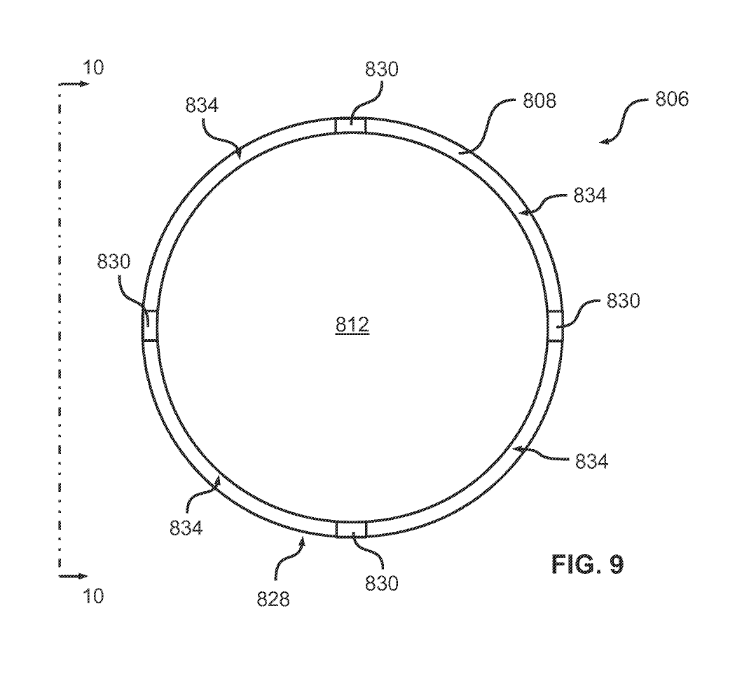

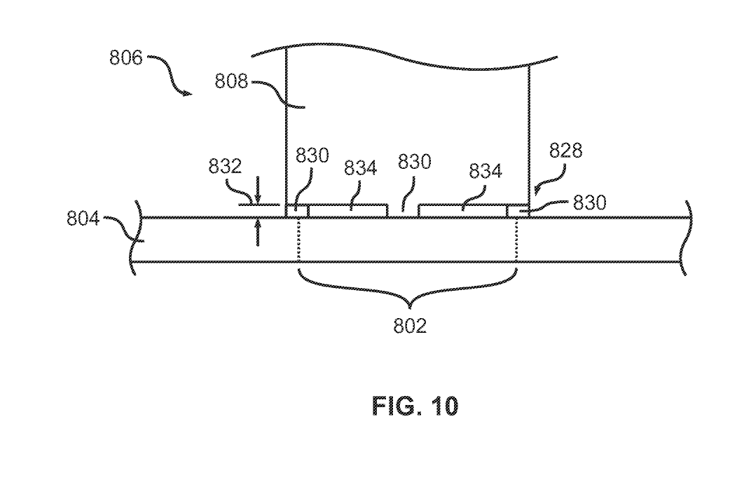

Referring now to FIG. 8 in combination with FIGS. 9 and 10, a bottom end (or edge) 828 of the liquid container 806 (and/or of the side wall 808 thereof) defines an opening adjacent to the substrate 804 (i.e., such that the substrate 804 is exposed to the interior 812) and has a plurality of stand-offs (or protrusions) 830 formed thereon. In the depicted embodiment, four stand-offs 830 are included, but in other embodiments, a different number may be used. In some embodiments, the stand-offs have a height (or thickness) 832 of, for example, between about 0.1 millimeter (mm) and about 1.0 mm. The liquid container 806 may be positioned adjacent to the substrate 804 such that the stand-offs 830 contact the substrate 804 (or an upper surface thereof). In some embodiments, the stand-offs 830 are the only portions of the liquid container 806 that contact the substrate 804, while gaps (or spaces) 834 (e.g., equal in height to the stand-offs 830) are formed between the other portions of the liquid container 806 and the substrate 804.

In operation, a processing liquid 836 is delivered into the interior 812 of the liquid container 806 through, for example, fluid line 818. In some embodiments, the processing liquid 836 does not completely fill the interior 812 of the liquid container 806. Thus, the processing liquid 836 may be understood to divide the liquid container 806 (and/or the interior 812 thereof) into a first portion 838 and a second portion 840. As is shown in FIG. 8, the first portion 838 may be considered to be the portion of the liquid container 806 that is occupied by the processing liquid 836, and the second portion 840 may be considered to be the portion of the liquid container 806 that is devoid of the processing liquid 836 (e.g., the portion above the surface of the processing liquid 836).

Due to gravity, the processing liquid 836 may tend to flow from the interior 812 of the liquid container 806 through the gaps 834 (FIGS. 9 and 10) and onto other portions of the substrate 804 (i.e., besides the site-isolated region 802). However, in some embodiments, the gaseous pressure in the second portion 840 of the interior 812 of the liquid container 806 is reduced such that a “suction” force is exerted on the liquid 836, causing it to remain within the interior 812 of the liquid container 806 so that the only portion of the substrate 804 the liquid 836 contacts is the site-isolated region 802.

More specifically, in some embodiments, a partial vacuum is applied to the second portion 840 of the interior 812 of the liquid container 806 through fluid line 814 (and the liquid trap 822) to create an under-pressure gaseous environment in the second portion 840 of the interior 812. In some embodiments, the partial vacuum is applied while the liquid 836 is being dispensed into the interior 812 to prevent any of the liquid 836 from flowing onto portions of the substrate 804 besides the site-isolated region.

In the event that any of the liquid 836 is drawn into fluid line 814 and into the liquid trap 822, the liquid 836 may be detected by the liquid sensor 824. In response, the system may appropriately adjust the strength of the partial vacuum being applied to prevent any further liquid 836 from being drawn through fluid line 814. Additionally, the strength of the partial vacuum may be adjusted to alter the size of the region of the substrate 804 being processed.

For example, a slight increase in the strength of the partial vacuum may pull the liquid 836 towards the center of the site-isolated region 802, essentially reducing the size the processed region (i.e., the site-isolated region 802). Likewise, a slight decrease in the strength of the partial vacuum may allow the liquid 836 to flow farther from the center of the site-isolated region 802, essentially increasing the size of the processed region, and perhaps causing (or allowing) the liquid 836 to leak from the liquid container 806. However, it should also be noted that if the strength of the partial vacuum is too great, gas (e.g., air) may be pulled through the gaps 834, causing bubbles to form (or bubbling to occur) within the liquid 836, which may also result in the liquid 836 leaking from the liquid container 806 (i.e., through the gaps 834, due to a loss of the effective suction).

It should also be understood that the strength of the partial vacuum may be adjusted to accommodate for processing liquids with different viscosities. That is, the strength of the partial vacuum may be increased for liquids with relatively low viscosities, and vice versa. In some embodiments, the strength of the partial vacuum is such that the suction force (or pressure) caused by the under-pressure gaseous environment in the second portion 840 of the interior 812 is between about −1.300 kilopascal (kPa) and about −0.200 kPa.

After the processing is complete, the processing liquid 836 may be removed from the interior 812 of the liquid container 806 through, for example, fluid line 816. As referred to above, fluid line 816 may extend into the interior 812 to facilitate the removal of the liquid 836.

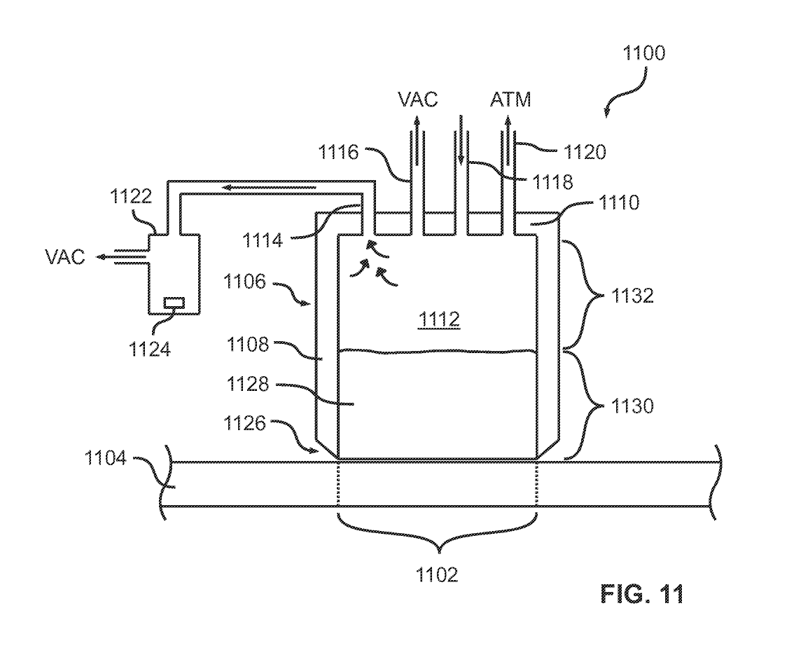

FIG. 11 schematically illustrates a wet processing unit 1100, according to some embodiments, positioned above a site-isolated region 1102 on a substrate 1104. The wet processing 1100 shown in FIG. 11 may be similar to the wet processing unit 800 shown in FIGS. 8, 9, and 10 in some respects. For example, the wet processing unit 1100 includes a liquid container 1106 having a side wall 1108 and a top portion 1110, which along with the substrate 1104, at least partially enclose an interior 1112.

The top portion 1110 of the liquid container 1106 has fluid lines 1114-1118 inserted therethrough. Fluid line 1114 is in fluid communication with a liquid trap assembly 1122 having a liquid/leak sensor 1124 therein, which is in fluid communication with a vacuum line, as is fluid line 1116. Fluid line 1118 may be in fluid communication with one or more of the processing fluid supplies within the processing fluid supply system 304 (FIG. 3). In some embodiments, fluid line 1120 is in fluid communication with the atmosphere (and unlike the embodiment shown above, fluid line 1120 is not plugged). Although not shown, it should be understood that in some embodiments at least some of the fluid lines 1114-1120 extend into the interior 1112 of the liquid container 1106.

Still referring to FIG. 11, a bottom end (or edge) 1126 of the liquid container 1106 (and/or of the side wall 1108 thereof) defines an opening adjacent to the substrate 1104 and is tapered as shown. The liquid container 1106 may be positioned adjacent to the substrate 1104 such that the tapered bottom end 1126 is substantially in contact with the substrate 1104. However, although not specifically shown, it should be understood that small gaps (e.g., less than 0.5 mm, such as less than 0.1 mm) may be formed between portions of the substrate 1104 and the liquid container 1106 along some portions of the bottom end 1126 due to, for example, variations in the substrate 1104 and/or liquid container 1106. In some embodiments, the liquid container 1106 is positioned such that no portion of the liquid container 1106 contacts the substrate 1104, but rather, a small gap (e.g., less than 0.5 mm, such as less than 0.1 mm) is formed between the entire bottom end 1126 of the liquid container 1106 and the substrate 1104.

The wet processing unit 1100 shown in FIG. 11 may operate in a manner similar to that described above. That is, a processing liquid 1128 may be dispensed into the interior 1112 of the liquid container 1106 and may be understood to divide the interior 1112 into a first portion 1130 (occupied by the processing liquid 1128) and a second portion 1132 (devoid/above the processing liquid 1128).

To prevent the processing liquid 1128 from flowing through any gaps between the bottom end 1126 of the liquid container 1106 and the substrate 1104 (and thus keep the liquid 1128 on the site-isolated region 1102), an under-pressure gaseous environment may be formed in the second portion 1132 of the interior 1112. In a manner similar to that described above, the under-pressure gaseous environment may be formed by applying a partial vacuum to the second portion 1132 of the interior 1112 of the liquid container 1106 through fluid line 1114 and the size of the portion of the substrate 1104 contacted by the liquid 1128 (e.g., the site-isolated region 1102) may be adjusted by varying the strength of the partial vacuum. After the processing is completed, the liquid 1128 may be removed from the interior 1112 of the liquid container 1112 through fluid line 1116.

Due to the minimal contact area between the liquid containers and the substrate, any contamination caused by the liquid container is minimized. However, due to the suction force described above, the processing liquid may be controlled so that it only processes the desired portion(s) of the substrate. It should also be noted that in at least some embodiments, no sealing member (e.g., a rubber or silicone o-ring) is used to form a seal around the site-isolated regions, which further reduces contamination when compared to some conventional processing systems.

In this manner, the system 300 (FIG. 3) may simultaneously perform any of numerous wet processing methods on the regions 320 of the substrate 316. Examples of wet processes include wet cleanings (e.g., using a solution of ammonium hydroxide (NH₄OH), hydrogen peroxide (H₂O₂), and deionized (DI) water (H₂O)), wet etches and/or strips, and electroless depositions. In some embodiments, although not shown in FIGS. 8-11, the transducers 338 (and/or the transducer actuators 336) are used, such as during the wet processing.

In some embodiments, the wet processing system 300 (e.g., particularly the processing fluid supply system 304 and/or the control system 306) is configured to intentionally vary (or create differences between) the processing conditions for the wet processes performed on two or more of the regions 320 (i.e., combinatorial processing). Exemplary variations generated between two or more of the reactions include varying the chemical compositions, pH levels, temperatures of the processing fluids (including any processing gases), reaction times, processing fluid volumes, parameters related to the operation of the transducers 338 (i.e., in embodiments which include the transducers 338), and/or any combination thereof.

It should be understood that the size, shape, and number of the liquid containers and/or the corresponding regions on the substrate may be different in other embodiments. For example, in some embodiments, the substrate may include four regions, each of which essentially occupies a quadrant on the substrate. In some embodiments, the regions may be in the shape of parallel strips extending across the substrate. It should be understood that in such embodiments, the liquid containers may be sized and shaped in such a way to as to seal these different sizes/shapes of regions.

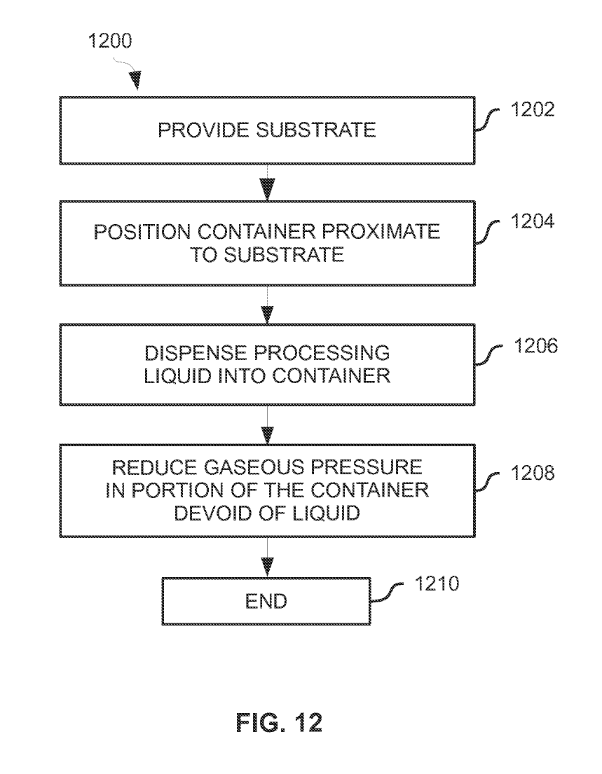

FIG. 12 illustrates a method 1200 for processing a substrate according to some embodiments. At block 1002, the method 100 begins by providing a substrate. The substrate may have a plurality of site-isolated regions thereon, such as the substrates described above.

At block 1204, a container is positioned proximate to the substrate. In some embodiments, the container has an opening at end thereof adjacent to the substrate. The container may be positioned proximate to one of the site-isolated regions on the substrate. In some embodiments, the container is positioned and shaped such that after the container is positioned, at least one gap is formed between at least a portion of the container and the substrate. In some embodiments, at least a portion of the container contacts the substrate.

At block 1206, a processing liquid is dispensed into the container. The processing liquid may contact the substrate through the opening at the end thereof. In some embodiments, the processing liquid does not completely fill the container such that the interior of the container is divided into a first portion (or region), which is occupied by the liquid, and a second portion, which is devoid of (e.g., above) the liquid.

At block 1208, the gaseous pressure in the second portion of the interior of the container is reduced to create an under-pressure gaseous environment in the second portion of the interior. More specifically, in some embodiments, a partial vacuum is applied to the second portion of the interior of the container which causes a suction force to be exerted on the liquid. The suction force prevents the liquid from flowing from the respective site-isolated region through the at least one gap onto other regions (e.g., other site-isolated regions) on the substrate.

Although not shown in FIG. 12, the processing liquid may be used to perform a wet process (e.g., a wet cleaning process) on the respective site-isolated region of the substrate. After the wet process is completed, the liquid may be removed from the container (e.g., through a manifold different than the one used to create the suction force). In some embodiments, the method 1000 is performed simultaneously on multiple site-isolated regions on the substrate, perhaps in a combinatorial manner, using multiple containers. At block 1210, the method 1000 ends.

Thus, in some embodiments, methods for processing a substrate are provided. A substrate having a first region and a second region is provided. A container is positioned proximate to the first region of the substrate. The container has an opening on an end thereof adjacent to the substrate. A processing liquid is dispensed into the container such that the processing liquid contacts the first region of the substrate through the opening. A gaseous pressure in a portion of the container devoid of the processing liquid is reduced. The reduction of the gaseous pressure prevents the processing liquid from flowing from the first region of the substrate to the second region of the substrate.

In some embodiments, methods for processing a substrate are provided. A substrate having a surface with a first region and a second region is provided. A container is positioned proximate to the first region of the surface of the substrate. The container has an opening on an end thereof adjacent to the surface of the substrate. The container is shaped such that a gap extends between at least a portion of the end of the container at the surface of the substrate. A processing liquid is dispensed into the container such that the processing liquid contacts the first region of the surface of the substrate through the opening. A partial vacuum is applied to a portion of the container devoid of the processing liquid. The application of the partial vacuum causes a force to be exerted on the processing liquid such that the processing liquid is prevented from flowing from the first region of the substrate to the second region of the substrate through the gap.

In some embodiments, methods for processing a substrate are provided. A substrate having a surface with a first region and a second region is provided. A container is positioned proximate to the first region of the surface of the substrate. The container has an opening on an end thereof adjacent to the surface of the substrate. The container includes a plurality of protrusions extending from the end thereof. After the positioning the container proximate to the first portion of the substrate, the at least one protrusion is in contact with the surface of the substrate and at least one gap is formed between the plurality of protrusions, the end of the container, and the surface of the substrate. A processing liquid is dispensed into the container such that the processing liquid contacts the first region of the surface of the substrate through the opening. A partial vacuum is applied to a portion of the container devoid of the processing liquid through a first manifold formed through the container. The application of the partial vacuum causes a force to be exerted on the processing liquid such that the processing liquid is prevented from flowing from the first region of the substrate to the second region of the substrate through the at least one gap. The processing liquid is removed from the container through a second manifold formed through the container.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for processing a substrate, the method comprising:
providing a substrate having a first region and a second region;
positioning a container proximate to the first region of the substrate, the container comprising a first opening on an end thereof adjacent to the substrate and a second opening above the end adjacent to the substrate;
dispensing a processing liquid into the container such that the processing liquid contacts the first region of the substrate through the opening; and
reducing a gaseous pressure in a portion of the container devoid of the processing liquid through the second opening, said reduction of the gaseous pressure preventing the processing liquid from flowing from the first region of the substrate to the second region of the substrate and not causing any of the processing liquid to be drawn from the container through the second opening.

2. The method of claim 1, wherein after the positioning the container proximate to the first region of the substrate, a gap extends between at least a portion of the end of the container and the substrate.

3. The method of claim 2, wherein the container comprises at least one protrusion on the end thereof adjacent to the substrate, and wherein after the positioning the container proximate to the first region of the substrate, the at least one protrusion is in contact with the substrate.

4. The method of claim 3, wherein the gap has a height of between about 0.1 mm and about 1.0 mm.

5. The method of claim 1, wherein the portion of the container devoid of the processing liquid is above the processing liquid in the container.

6. The method of claim 5, wherein the reducing the gaseous pressure in the portion of the container devoid of the processing liquid comprises applying a partial vacuum to the portion through the second opening.

7. The method of claim 6, wherein the applying the partial vacuum causes an under-pressure gaseous environment to be formed in the portion of the container devoid of the processing liquid, and wherein a force of the under-pressure gaseous environment is between about −1.300 kPa and about −0.200 kPa.

8. The method of claim 1, wherein the container has a cylindrical shape.

9. The method of claim 1, wherein the end of the container adjacent to the surface of the substrate has a tapered shape.

10. The method of claim 1, wherein the container further comprises a vent manifold in fluid communication with the atmosphere, and further comprising blocking the vent manifold before the reducing the gaseous pressure in the portion of the container devoid of the processing liquid.

11-15. (canceled)

16. A method for processing a substrate, the method comprising:
providing a substrate having a surface with a first region and a second region;
positioning a container proximate to the first region of the surface of the substrate, the container having an opening on an end thereof adjacent to the surface of the substrate, wherein the container comprises a plurality of protrusions extending from the end thereof, and wherein after the positioning the container proximate to the first portion of the substrate, the at least one protrusion is in contact with the surface of the substrate and at least one gap is formed between the plurality of protrusions, the end of the container, and the surface of the substrate;
dispensing a processing liquid into the container such that the processing liquid contacts the first region of the surface of the substrate through the opening;
applying a partial vacuum to a portion of the container devoid of the processing liquid through a first manifold formed through the container, said application of the partial vacuum causing a force to be exerted on the processing liquid such that the processing liquid is prevented from flowing from the first region of the substrate to the second region of the substrate through the at least one gap and none of the processing liquid is drawn from the container through the first manifold; and
removing the processing liquid from the container through a second manifold formed through the container.

17. The method of claim 16, wherein
the partial vacuum is applied through a liquid trap in fluid communication with the first manifold, wherein the liquid trap comprises a liquid sensor configured to detect if some of the processing liquid is drawn from the container through the first manifold.

18. The method of claim 16, wherein the second manifold is formed through the container adjacent to the portion of the container devoid of the processing liquid.

19. The method of claim 16, further comprising adjusting the strength of the partial vacuum, said adjusting of the strength of the partial vacuum altering the size of an area of the substrate contacted by the processing liquid.

20. The method of claim 16, wherein the container has a cylindrical shape.

21. A method for processing a substrate, the method comprising:
providing a substrate having a surface with a plurality of first regions and second regions on opposing sides of each of the plurality of first regions;
positioning a container proximate to each of the plurality of first regions of the surface of the substrate, each of the containers having an opening on an end thereof adjacent to the surface of the substrate, wherein after the positioning each of the containers proximate to the respective first portion of the substrate, at least one gap is formed between the end of the respective container and the surface of the substrate;
dispensing a processing liquid into each of the containers such that the processing liquid contacts the respective first regions of the surface of the substrate through the opening of each of the containers;
applying a partial vacuum to a portion of each of the containers devoid of the processing liquid through a first manifold formed through the each of the containers, said application of the partial vacuum causing a force to be exerted on the processing liquid such that the processing liquid is prevented from flowing from the first regions of the substrate to the second regions of the substrate through the gaps and none of the processing liquid is drawn from the containers through the first manifolds;
combinatorially varying at least one processing condition associated with the processing liquid dispensed into the containers; and
removing the processing liquid from the containers through a second manifold formed through the each of the container.

22. The method of claim 21, wherein the at least one processing condition associated with the processing liquid comprises one or more of a chemical composition of the processing liquid, a pH level of the processing liquid, a temperature of the processing liquid, a reaction time of the processing liquid, and a volume of the processing liquid.

23. The method of claim 21, wherein the partial vacuum is applied to the portion of each of the plurality of containers devoid of the processing through a liquid trap in fluid communication with the respective first manifold, wherein each liquid trap comprises a liquid sensor configured to detect if some of the processing liquid is drawn from the respective container through the first manifold.
